(19) United States
(12) Patent Application Publication
(10) Pub. No.: US 2019/0052054 A1
(43) Pub. Date: Feb. 14, 2019

(54) LASER ARRANGEMENT, METHOD FOR CONTROLLING LASER AND MEASURING METHOD

(71) Applicant: FRAUNHOFER-GESELLSCHAFT ZUR FÖRDERUNG DER ANGEWANDTEN FORSCHUNG E.V., München (DE)

(72) Inventors: Magnus HAPPACH, Berlin (DE); David DE FELIPE MESQUIDA, Berlin (DE); Martin SCHELL, Berlin (DE); Norbert KEIL, Berlin (DE)

(73) Assignee: FRAUNHOFER-GESELLSCHAFT ZUR FÖRDERUNG DER ANGEWANDTEN FORSCHUNG E.V., Müchen (DE)

(21) Appl. No.: 16/076,992

(22) PCT Filed: Feb. 10, 2017
(86) PCT No.: PCT/EP2017/053051

§ 371 Date: Aug. 9, 2018

(30) Foreign Application Priority Data
Feb. 12, 2016 (DE) 10 2016 202 210.5

(51) Int. Cl. H01S 5/068; H01S 5/14; H01S 5/10

(52) U.S. Cl. CPC H01S 5/06808; H01S 5/1021; H01S 5/146; H01S 5/142

(57) ABSTRACT

A laser arrangement includes a laser having a laser cavity, at least one cavity external to the laser, which reflects one part of the light emitted by the laser back into the laser cavity, and a voltage measuring device for measuring a voltage on an active section of the laser. By means of the measured voltage a detuning of the emission wavelength of the laser and/or a property of a material adjacent to the external cavity can be determined. The external cavity includes an optical waveguide coupled to the laser.

### CROSS-REFERENCE TO A RELATED APPLICATION

This application is a National Phase Patent Application of International Patent Application Number PCT/EP2017/053051, filed on Feb. 10, 2017, which claims priority of German Patent Application 10 2016 202 210.5, filed on Feb. 12, 2016.

### BACKGROUND

This invention relates to a laser arrangement, a method for controlling a laser and a measuring method.

It is known from the prior art to provide an external cavity in addition to an internal cavity of a laser, which reflects at least one part of the light emitted by the laser back into the laser cavity. The light reflected back interferes with the light in the laser cavity, which has an influence on the electric voltage on an active section of the laser. For example, the article “Distance Measurement using the Change in Junction Voltage Across a Laser Diode due to the Self-Mixing Effect”, Lim, Yah Leng et al., Microelectronics, MEMS, and Nanotechnology, International Society for Optics and Photonics, 2005 describes an external cavity cooperating with a laser in a free-beam arrangement, wherein by means of the electric voltage on an active section of the laser a distance of a reflecting element of the free-beam cavity is determined. The influence of the light fed back by an external cavity on the laser is also described in the article Goldberg, Lew, et al. “Spectral characteristics of semiconductor lasers with optical feed-back.” Microwave Theory and Techniques, IEEE Transactions on 30.4 (1982): 401-410.

### SUMMARY

The problem to be solved by the invention consists in simplifying the stabilization of the emission wavelength of a laser as well as measurements by means of a laser.

This problem is solved by a laser arrangement with features as described herein, by a method for controlling a laser with features as described herein, and by a measuring method with features as described herein.

Accordingly, there is provided a laser arrangement, comprising:
a laser comprising a laser cavity;
at least one cavity external to the laser, which reflects one part of the light emitted by the laser back into the laser cavity;
a voltage measuring device for measuring a voltage on an active section of the laser, wherein by means of the measured voltage a detuning of the emission wavelength of the laser and/or a property of a material adjacent to the external cavity can be determined, wherein
the external cavity includes an optical waveguide coupled to the laser.

The optical waveguide of the external cavity for example is an integrated optical waveguide or a fiber waveguide (in particular a glass fiber, e.g. an APC glass fiber).

As already mentioned above, the light reflected back by the external cavity into the laser cavity interferes with the light in the laser cavity, which leads to a change in the voltage on an active section (gain section) of the laser. In particular, the interference changes the laser condition, which results in a change in the voltage on the active section of the laser, in particular in a dependence or a changed dependence of the voltage on the active section on the emission wavelength of the laser. Correspondingly, a (e.g. thermally induced) change (detuning) of the emission wavelength leads to a change in the voltage on the active section, so that a detuning of the emission wavelength can be determined with reference to the voltage on the active section. The voltage on the active section thus serves as a monitor signal. An additional optical component (such as e.g. a filter or a photodiode) for generating a feedback signal (monitor signal) for the wavelength stabilization thus is not absolutely necessary. Rather, merely the voltage on the active section is used for a correction of the emission wavelength. This provides for e.g. a rather high output power and a rather compact construction of the laser. Furthermore, undesired disturbances are avoided for example by optical filters. The formation of the external cavity with an optical (e.g. integrated optical) waveguide in addition supports the realization of a compact construction and in particular provides for the realization of a chip-integrated measuring device for determining material properties. It is also conceivable that the laser arrangement includes more than one external cavity. For example, at least two external cavities are present, which have different optical lengths. By means of such external cavities a voltage signal can be generated which allows a determination of the wavelength, so that a wavelength measuring device can be realized.

For example, the laser includes a Bragg grating as a reflecting resonator element; for example, the laser is configured in the form of a DBR laser. The interference of the light reflected back into the laser cavity with the light in the laser cavity leads to the fact that the reflectivity of the Bragg grating becomes wavelength-dependent or the wavelength dependence of the Bragg grating is changed. Due to this wavelength-dependent reflectivity of the Bragg grating the laser condition R1*R2*exp(2*L_{cav}*(g-a)) is changed, wherein R1, R2 designate the reflectivities of the resonator mirrors, L_{cav} designates the length of the laser cavity, g the amplification, and a the losses of the laser cavity. With a lower reflectivity of the Bragg grating the gain coefficient of the active section of the laser increases, whereas it decreases with a higher reflectivity. A higher gain factor is obtained by a higher number of charge carriers in the conduction band and therefore makes itself noticeable in the voltage measured on the active section of the laser.

The fact that the waveguide of the external cavity can be an “integrated optical waveguide” in particular means that the waveguide can have a core and/or shell formed on a substrate. For example, the integrated optical waveguide of the external cavity is formed on a semiconductor substrate, wherein the core and/or the waveguide shell is formed e.g. by at least one semiconductor layer, silicon dioxide or silicon nitride. It is also conceivable, however, that the waveguide of the external cavity is a polymer waveguide.

It is further noted that the laser can very well also be an external-cavity laser, i.e. a laser which itself has an external cavity. This external cavity, however, is part of the “laser cavity” (e.g. together with a cavity formed by the active section of the laser). Correspondingly, the external cavity of the laser arrangement according to the invention is different from the external cavity of an external-cavity laser.

According to a development of the invention, the laser cavity includes an integrated optical waveguide that is coupled to the waveguide of the external cavity. It is conceivable that the coupling of the two waveguides is effected in that at least one sub-section of the waveguide of the external cavity is formed integrally with the waveguide of the laser cavity, i.e. at least one part of the laser cavity and at least one part of the external cavity are formed by the same waveguide. For example, however, the laser cavity is delimited from the external cavity by a reflecting element, for example in the form of an integrated Bragg grating.

According to another aspect of the invention, a first sub-section of the waveguide of the external cavity is formed of a different material than a second sub-section of the waveguide. For example, the first sub-section of the waveguide of the external cavity is formed on a first substrate integrally with a waveguide of the laser cavity, while the second sub-section of the waveguide of the external cavity is formed on a second substrate (in particular different from the first substrate) and is coupled to the first sub-section of the waveguide. In particular, the second substrate and/or the second sub-section of the waveguide of the external cavity consists of a different material than the first substrate and/or the first sub-section of the waveguide of the external cavity.

It is of course also conceivable that the entire waveguide of the external cavity is formed on a different (separate) substrate and of a different material than the waveguide of the laser cavity. The coupling between the external cavity and the laser cavity or between the first and the second sub-section of the waveguide of the external cavity is effected for example by a cohesive connection. It is conceivable that coupling is effected by means of an optical coupler (e.g. a directional coupler), which in particular also is arranged on the substrate (chip) of the laser.

The voltage on the active section of the laser in particular depends on the design of the external cavity, wherein the voltage has wavelength-dependent maxima. According to an exemplary embodiment of the invention, the external cavity is designed and adjusted to the laser cavity such that the location of the voltage maxima (i.e. the wavelength at which the voltage reaches a maximum) is at least approximately independent of the temperature. It is conceivable here that a wavelength stabilization is effected by wobbling around such a maximum of the voltage.

For example, at least one sub-section of the waveguide of the external cavity has a thermo-optical coefficient and/or a coefficient of thermal expansion that is different from the thermo-optical coefficient and/or the coefficient of thermal expansion of the waveguide of the laser cavity.

It is also conceivable that the waveguide of the external cavity has a first and a second sub-section as described above, wherein the second portion of the waveguide can be designed such that it has a thermo-optical coefficient and/or a coefficient of thermal expansion that is different from the thermo-optical coefficient and/or the coefficient of thermal expansion of the first portion of the waveguide. For example, the second portion of the waveguide has a dielectric core (e.g. of silicon nitride) and a polymer shell. Such waveguides can have a negative thermo-optical coefficient depending on their dimensions.

According to another aspect of the invention the optical length of the external cavity is an integer multiple of the optical length of the laser cavity. It thereby is achieved that the overlap of the modes of the laser cavity and of the external cavity is as large as possible, whereby e.g. an impairment of the laser stability and a shift of mode hops can be counteracted.

It is also conceivable that the optical length Lₑₓₜ of the external cavity is chosen in dependence on a desired free spectral range (FSR) with respect to oscillations of the voltage on the active section. For example, with a desired FSR of 100 GHz an optical length Lₑₓₜ of 1499 μm is used, with an FSR of 50 GHz an optical length Lₑₓₜ of 2998 μm, with an FSR of 25 GHz an optical length Lₑₓₜ of 5996 μm, and with an FSR of 12.5 GHz an optical length Lₑₓₜ of 11991 μm.

The laser arrangement according to the invention can also include an evaluation unit that is configured and provided to determine a change in the emission wavelength of the laser (for example due to temperature changes) and/or a property of a material adjacent to the external cavity in dependence on the voltage measured on the active section. The determination of the property of the material in particular is possible because properties or a change in properties of the adjacent material changes the effective index of refraction of at least one sub-section of the waveguide of the external cavity and hence the phase shift with which the light reflected back enters into the laser cavity, and thus changes the voltage on the active section of the laser. The property for example is a material property (for example a material concentration) or another quantity (for example the temperature and/or a mechanical tension of the material). The material to be measured for example is a liquid or a gas. The laser arrangement according to the invention in particular is integrated into a common chip, so that for example an on-chip liquid or gas measuring device can be realized.

It is also conceivable that the evaluation unit is configured and provided to regulate and thus stabilize the emission wavelength of the laser in dependence on the voltage measured on the active section. The laser arrangement according to the invention thus can be used for example in the field of communications engineering; e.g. as a wavelength-stabilized laser in optical communication networks (for example DWDM—Dense Wavelength Division Multiplexing) or in medicine (e.g. for carrying out blood analyses). What is also conceivable is a use in coherent optical systems.

For example, the laser has a heatable phase section and/or a heatable Bragg grating section, wherein the evaluation unit is configured to vary the temperature of the phase section and/or the Bragg grating section for regulating the emission wavelength. The phase section and the Bragg grating section for example include heating electrodes that can be actuated by the evaluation unit. For example, the evaluation unit and the voltage measuring device form a common unit (e.g. in the form of a correspondingly programmable device).

The laser of the laser arrangement according to the invention for example is a hybrid laser that comprises a first waveguide portion formed on the basis of a semiconductor material (which for example comprises the active section of the laser) and a second waveguide portion formed on the basis of a polymer material. It is of course also conceivable that the laser and also a sub-section of the external cavity are continuously made of the same semiconductor material such as indium phosphide, wherein however the compensation member is formed of a material that has different thermal properties, as explained above.

The invention also relates to a method for controlling a laser, in particular a laser arrangement as described above, comprising the following steps:
providing a cavity external to the laser, which reflects one part of the light emitted by the laser back into the laser cavity; wherein
the external cavity includes an waveguide coupled to the laser;
measuring a voltage on an active section of the laser; and
regulating the emission wavelength of the laser in dependence on the voltage measured on the active section.

In a further aspect the invention also relates to a measuring method, comprising the following steps:
providing a laser arrangement, in particular as described above, with a laser comprising a laser cavity and a cavity external to the laser, which reflects one part of the light emitted by the laser back into the laser cavity, wherein
the external cavity includes a waveguide coupled to the laser;
measuring a voltage on an active section of the laser; and
determining at least one property of at least one material (e.g. present on the external cavity or its waveguide and/or at least sectionally extending around the external cavity or its waveguide) adjacent to the external cavity (in particular adjacent to its waveguide).

The developments described above with respect to the laser arrangement can of course analogously be used in the methods according to the invention.

### BRIEF DESCRIPTION OF THE DRAWING

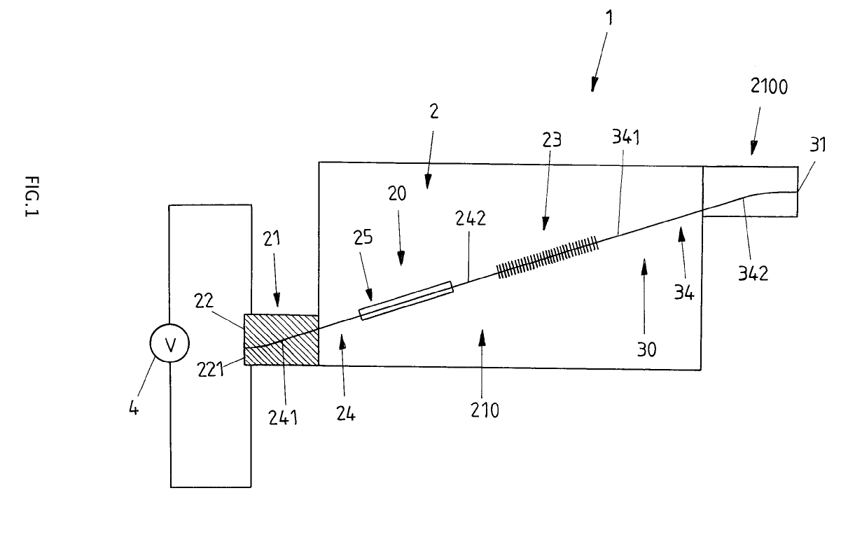

The invention will be explained in detail below by means of an exemplary embodiment with reference to the only FIG. 1. FIG. 1 schematically shows a top view of a laser arrangement according to the invention with a laser and an external cavity.

### DETAILED DESCRIPTION

More exactly, the laser arrangement 1 shown in FIG. 1 comprises a laser in the form of an integrated optical hybrid DBR laser 2. The laser 2 comprises an active semiconductor section 21 with a front side 22 that is provided with a highly reflecting coating 221. For example, the semiconductor section 21 is formed on an indium phosphide substrate. The highly reflecting coating 221 forms a first reflecting resonator element of a cavity 20 of the laser 2.

To the active semiconductor section 21 a polymer section 210 of the laser 2 is coupled, which comprises a Bragg grating 23 that forms a second resonator element of the cavity 20 of the laser 2. The cavity 20 of the laser 2 furthermore comprises an integrated optical waveguide 24 that extends from the highly reflecting coating 221 of the active section 21 up to the Bragg grating 23. The waveguide 24 includes a first sub-section 241 that extends in the region of the active section 21 and correspondingly is formed by layers of a semiconductor material. A second sub-section 242 of the waveguide 24 extends as a polymer waveguide in the polymer section 210. The two sub-sections 241, 242 of the waveguide 24 are coupled to each other, wherein at least one coupling facet of the waveguide portions 241, 242 can have an anti-reflection coating. Beside the Bragg grating 23 the polymer waveguide portion 242 also comprises a phase section 25. Both the Bragg grating 23 and the phase section 25 are designed to be heatable, i.e. in the region of the Bragg grating 23 and the phase section 25 heating electrodes are provided. The basic construction of the DBR laser 2 is described in the article de Felipe, D. e., “Polymer-based external cavity lasers: tuning efficiency, reliability, and polarization diversity.” Photonics Technology Letters, IEEE 26.14 (2014): 1391-1394, to which reference in so far is made expressly.

The laser arrangement 1 according to the invention furthermore comprises an external cavity 30, which extends from the Bragg grating 23 up to an outlet 31 of the external cavity 33. Thus, the Bragg grating 23 at the same time also forms a first reflecting resonator element of the external cavity 30, wherein a second resonator element delimiting the external cavity 30 for example is formed by a correspondingly reflecting coating of the outlet 31 or by another reflecting element. It is noted that the laser described in the above-mentioned article (similar to the laser 2) is an external-cavity laser, i.e. the laser itself has an external cavity that forms one part of the laser cavity. This external cavity of the laser is of course different from the external cavity 30.

The external cavity 30 likewise includes an integrated optical waveguide 34. This integrated optical waveguide 34 consists of a first sub-section 341, which is formed by a continuation of the second sub-section 242 of the waveguide 24 of the laser cavity 20, i.e. the first sub-section 341 of the waveguide 34 of the external cavity 30 is integrally connected with the second sub-section 242 of the waveguide 24. A second sub-section 342 of the waveguide 34 of the external cavity 30 on the other hand is not formed as a polymer waveguide, but is part of a compensation section 2100 of another material, which is coupled to the substrate on which the polymer section 210 of the laser 2 is formed. It is conceivable that analogous to the active section 21 of the laser 2 the compensation section 2100 is formed on the basis of indium phosphide or another semiconductor material. Correspondingly, the second sub-section 342 of the waveguide 34 is formed by layers of a semiconductor material.

It is also possible, however, that the compensation section 2100 (in particular the waveguide portion 341) is formed on the basis of another material that has an index of refraction, a thermo-optical coefficient and/or a coefficient of thermal expansion different from the corresponding coefficients of the laser 2. For example, the waveguide portion 34 also can be formed on the basis of silicon dioxide, silicon, indium phosphide or silicon nitride. The first and the second sub-section 341, 342 of the waveguide 34 in particular are connected to each other via a cohesive connection (for example by using an adhesive).

As already mentioned above, coupling e.g. might also be effected by means of a coupler (e.g. a directional coupler, in particular a grating-assisted directional coupler). For example, the external cavity here comprises a waveguide (at least one waveguide portion) which is e.g. also arranged on the substrate of the laser cavity and is coupled to the laser cavity (or the waveguide portion 341) via the directional coupler. This waveguide is formed of a material (such as silicon dioxide or silicon nitride) that has different thermal properties (the above-mentioned coefficients) than the laser waveguide 242. The coupling points between the active section 21 and the polymer section 210 and/or between the polymer portion of the external cavity 320 and its compensation section 2100 can also have an anti-reflection coating.

It is also conceivable that instead of the integrated optical sub-section 341 a fiber waveguide (in particular a glass or polymer fiber) is used.

The external cavity 30 is designed such that light emitted by the laser 2 is partly reflected back into the laser cavity 20 (“optical feedback”). For example, an adhesive by which an optical fiber (not shown) is coupled to the outlet 31 of the compensation section 2100 generates the back-reflection or reflects at least one part of the light back into the laser cavity 20.

The light reflected back results in a wavelength dependence of the reflectivity of the Bragg grating 23 and hence of the laser condition. Correspondingly, a change in the emission wavelength of the laser 2 will make itself noticeable in a change in an electric voltage on the active section 21, as already explained above.

The electric voltage on the active section 21 is determined by means of a voltage measuring device 4. For example, the voltage measuring device 4 is part of a controller for stabilizing the emission wavelength of the laser 2. The controller can be configured to actuate the heating electrodes of the Bragg grating 23 and/or the phase section 25 in dependence on the voltage determined by means of the voltage measuring device 4 in order to counteract a change in the emission wavelength, as likewise already described above.

The polymer section 210 of the laser 2 (and correspondingly the polymer portion of the external cavity 30 integrally connected to the same) has a different thermo-optical coefficient and coefficient of thermal expansion than the active section 21 and the compensation section 2100. In particular, the second sub-section 242 of the waveguide 24 and correspondingly the first sub-section 101 of the waveguide 34 of the external cavity have a different thermo-optical coefficient and coefficient of thermal expansion than the second sub-section 342 of the waveguide 34.

The optical length of the external cavity 30 and the material that forms the second sub-section 342 of the waveguide 34 are chosen such that the phase shift of the light reflected back into the laser cavity 20 by the external cavity 30 remains at least approximately constant with respect to the light exiting from the laser 2 even with a change in temperature of the laser 2 (i.e. of the active section 21 and the polymer section 210) and of the external cavity 30 (i.e. of its polymer portion and the compensation section 2100). This has the effect that the wavelength dependence of the Bragg grating 23 caused by the light reflected back at least approximately does not depend on the temperature, as likewise already explained above. Thus, the optical feedback no longer is temperature-dependent, but only depends on the wavelength. Correspondingly, it is possible to choose a maximum of the voltage on the active section as working point, wherein the voltage fluctuates (wobbles) around the maximum as a result of the wavelength regulation. The back-reflection by the external cavity can also lead to a reduction of the line width of the light emitted by the laser; e.g. by 1 MHz. However, this does not influence the function of the laser. For example, a wavelength with minimum line width can be chosen as working point about which “wobbling” occurs, i.e. which should be kept constant.

1. A laser arrangement, comprising
a laser comprising a laser cavity;
at least one cavity external to the laser, which reflects one part of the light emitted by the laser back into the laser cavity;
a voltage measuring device for measuring a voltage on an active section of the laser, wherein by means of the measured voltage a detuning of the emission wavelength of the laser and/or a property of a material adjacent to the external cavity can be determined, wherein:
the external cavity includes an optical waveguide coupled to the laser.

2. The laser arrangement according to claim 1, wherein the laser is an external-cavity laser, wherein the cavity external to the laser is different from an external cavity of the external-cavity laser.

3. The laser arrangement according to claim 1, wherein the optical waveguide of the external cavity is an integrated optical waveguide or a fiber waveguide.

4. The laser arrangement according to claim 1, wherein the laser cavity comprises an integrated optical waveguide that is coupled to the waveguide of the external cavity.

5. The laser arrangement according to claim 4, wherein a sub-section of the waveguide of the external cavity is formed integrally with the waveguide of the laser cavity.

6. The laser arrangement according to claim 1, wherein a first sub-section of the waveguide of the external cavity is formed of a different material than a second sub-section of the waveguide.

7. The laser arrangement according to claim 5, wherein a first sub-section of the waveguide of the external cavity is formed of a different material than a second sub-section of the waveguide and the first sub-section of the waveguide of the external cavity is formed integrally with a sub-section of the waveguide of the laser cavity.

8. The laser arrangement according to claim 1, wherein the external cavity is designed such that the wavelengths at which the voltage on the active section of the laser reaches a maximum is at least approximately independent of the temperature.

9. The laser arrangement according to claim 1, wherein at least one sub-section of the waveguide of the external cavity has a thermo-optical coefficient and/or a coefficient of thermal expansion that is different from the thermo-optical coefficient and/or the coefficient of thermal expansion of the waveguide of the laser cavity.

10. The laser arrangement according to claim 9, wherein the second sub-section of the waveguide of the external cavity has a thermo-optical coefficient and/or a coefficient of thermal expansion that is different from the thermo-optical coefficient and/or the coefficient of thermal expansion of the first portion of the waveguide of the external cavity.

11. The laser arrangement according to claim 1, wherein the optical length of the external cavity is an integer multiple of the optical length of the laser cavity.

12. The laser arrangement according to claim 1, further comprising an evaluation unit that is configured and provided to determine a detuning of the emission wavelength of the laser and/or a property of a material adjoining the external cavity in dependence on the voltage measured on the active section.

13. The laser arrangement according to claim 12, wherein the evaluation unit is configured and provided to regulate the emission wavelength of the laser in dependence on the voltage measured on the active section.

14. The laser arrangement according to claim 13, wherein the laser includes a heatable phase section and/or a heatable Bragg grating section, wherein the evaluation unit is configured to vary the temperature of the phase section and/or the Bragg grating section for regulating the emission wavelength.

15. The laser arrangement according to claim 1, wherein the laser is a hybrid laser that comprises a first portion formed on the basis of a semiconductor material and a second portion formed on the basis of a polymer material.

16. A method for controlling a laser comprising:
providing a cavity external to the laser, which reflects one part of the light emitted by the laser back into the laser cavity, wherein;
the external cavity includes a waveguide coupled to the laser;
measuring a voltage on an active section of the laser, and
regulating the emission wavelength of the laser in dependence on the voltage measured on the active section.

17. A measuring method, comprising
providing a laser arrangement, with a laser comprising a laser cavity and a cavity external to the laser, which reflects one part of the light emitted by the laser back into the laser cavity, wherein:
the external cavity includes a waveguide coupled to the laser;
measuring a voltage on an active section of the laser; and
determining at least one property of at least one material adjacent to the external cavity.
